(19) United States
(12) Patent Application Publication
(10) Pub. No.: US 2009/0236741 A1
(43) Pub. Date: Sep. 24, 2009

(54) CONDUCTIVE STRUCTURE OF A CHIP AND METHOD FOR MANUFACTURING THE SAME

(76) Inventors: Hsiang-Ming HUANG, (US); An-Hong Liu, (US); Yi-Chang Lee, (US); Hao-Yin Tsai, (US); Shu-Ching Ho, (US)

Correspondence Address: Muncy, Geissler, Olds & Lowe, PLLC, P.O. BOX 1364, FAIRFAX, VA, 22038-1364, US

(21) Appl. No.: 12/262,682

(22) Filed: Oct. 31, 2008

(30) Foreign Application Priority Data
Mar. 19, 2008 (TW) 097109739

(51) Int. Cl. H01L 23/488; H01L 21/44

(52) U.S. Cl. 257/737; 438/614; 257/E23.023; 257/E21.476

(57) ABSTRACT

A conductive structure of a chip and a method for manufacturing the conductive structure are provided. An under bump metal (UBM) is formed on the redistribution layer (RDL) by performing an electroless plating process. Subsequently, the solder bump is formed on the under bump metal for electrical connection. Thus, the photomask can be economized and the cost of manufacturing can be reduced.

This application claims priority to Taiwan Patent Application No. 097109739 filed on Mar. 19, 2008, the disclosures of which are incorporated herein by reference in their entirety.

### CROSS-REFERENCES TO RELATED APPLICATIONS

Not applicable.

### BACKGROUND OF THE INVENTION

1. Field of the Invention

The present invention provides a package conductive structure of a chip and a method for manufacturing the same. In particular, the package conductive structure has an under bump metal formed through an electroless plating process.

2. Descriptions of the Related Art

In modern advanced semiconductor manufacturing processes, semiconductor devices have been minimized to the nano-scale in mass production. Nano-scale packaging technologies applicable to such semiconductor devices have also emerged to accommodate the need of different products. Because the integrated circuit (IC) industry develops at a fast pace, ICs have become increasingly complex in design and are developing towards the system-on-chip (SOC) in which various functions are integrated on a single chip. Furthermore, SOCs are designed with an ever higher operating frequency and devices therein are shrunk increasingly in size. Hence, once the fabrication of an IC is completed on a wafer, the wafer has to be transferred to a packaging facility for subsequent dicing and packaging. The efficiency of the packaging process impacts the production cost and operational performance of the packaged chip. Accordingly, the package structure and material thereof have become more important.

As shown in FIGS. 1A to 1G, the chip package conductive structure of the prior art and a method for manufacturing the same are depicted therein. As depicted in FIG. 1A, the chip 11 is formed with a pad 131 and a first passivation layer 13 that partially exposes the pad 131 therethrough. Then, depending on the design requirements, a first under bump metal (UBM) 133 is formed on the partially exposed pad 131 through a photolithographic process, as shown in FIG. 1B. The first UBM 133 is made of Cr, Ti, Ni, Cu, or alloys thereof. Next, as shown in FIG. 1C, a redistribution layer (RDL) 15 is formed through a photolithographic process to overlay the first UBM 133 and the first passivation layer 13. The redistribution layer 15 is conventionally made of a conductive material selected from Al or Cu. With the redistribution layer 15, bumps that are subsequently formed may be electrically connected to the pad 131 without restricted by the location of the pad 131. The bumps may be re-arranged according to the actual requirements with enhanced flexibility in use. Subsequently, as shown in FIG 1D, a second passivation layer 17 is extensively formed to overlay the redistribution layer 15 and the first passivation layer 13 and then patterned through a lithographic process to partially expose the redistribution layer 15 at appropriate locations.

Next, as shown in FIG. 1E, a second UBM 135 is formed on the partially exposed redistribution layer 15. Then, as shown in FIG 1F, a bump 19 is solder plated or a solder ball is implanted onto the second UBM 135 to electrically connect with the second UBM 135. Finally, the bump 19 shown in FIG. 1F may be reflowed to obtain a ball bump 19 as shown in FIG. 1G. However, the package conductive structure of the chip 11 of the prior art and the method of forming the same still have the following disadvantages. Usually, a first UBM 133 is needed between the pad 131 and the redistribution layer 15 and a second UBM 135 is needed between the bump 19 and the redistribution layer 15 to provide a better adhesion effect and prevent the diffusion of conductive metal materials. However, the formation of the first UBM 133 and the second UBM 135 conventionally involves photolithographic processes which use expensive photomasks. The use of more photomasks leads to a higher production cost and renders the actual manufacturing process more complex, making it difficult to improve the yield of the process.

In view of this, it is important to simplify the chip package conductive structure and the manufacturing process thereof, thereby to save the use of photomasks and consequently reduce the cost.

### SUMMARY OF THE INVENTION

One objective of this invention is to provide a conductive structure of a chip, comprising a redistribution layer, a UBM and a bump. The redistribution layer is formed on the chip and has a first conductive area and a second conductive area, in which the first conductive area is electrically connected to the chip. The UBM is formed on the second conductive area of the redistribution layer and electrically connected to the redistribution layer. The UBM is an electroless plating layer. The bump is formed on and electrically connected to the UBM. Since the UBM of this invention is formed through an electroless plating process, the resulting UBM is more uniform in thickness compared to the structures of the prior art.

Another objective of this invention is to provide a method for manufacturing a conductive structure of a chip, comprising: forming a redistribution layer on a chip, wherein the redistribution layer has a first conductive area to electrically connect to the chip therethrough; forming an under bump metal (UBM) through an electroless plating process to electrically connect the redistribution layer through a second conductive area thereof; and forming a bump electrically connected to the UBM. Because the UBM of this invention is formed through an electroless plating process instead of a photolithographic process, the manufacturing method of this invention may not only save use of photomasks, but also simplify the process steps to improve the yield of chip packages, and thus reducing the production cost.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIGS. 1A to 1G are schematic views of a chip package conductive structure of the prior art; and

FIGS. 2A to 2F are schematic views of a chip package conductive structure of this invention and a method for manufacturing the same.

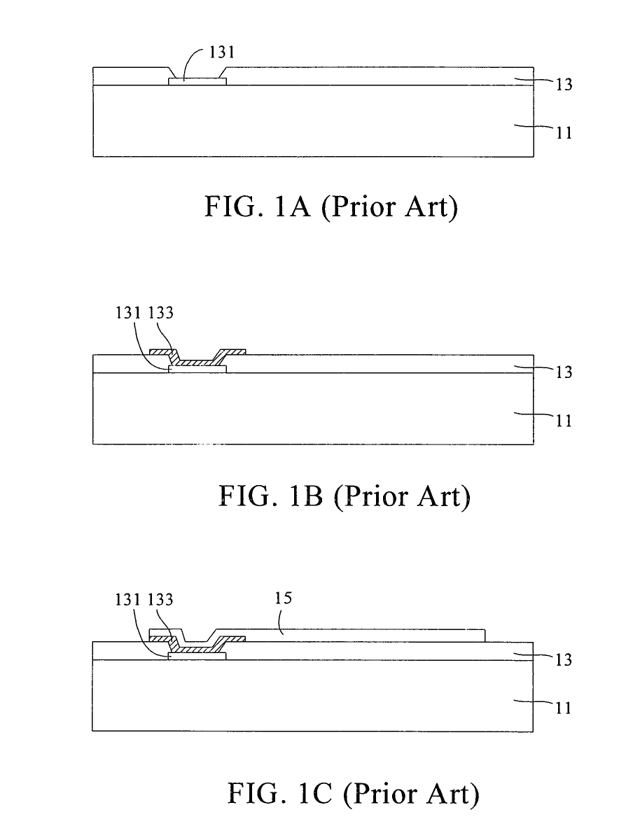

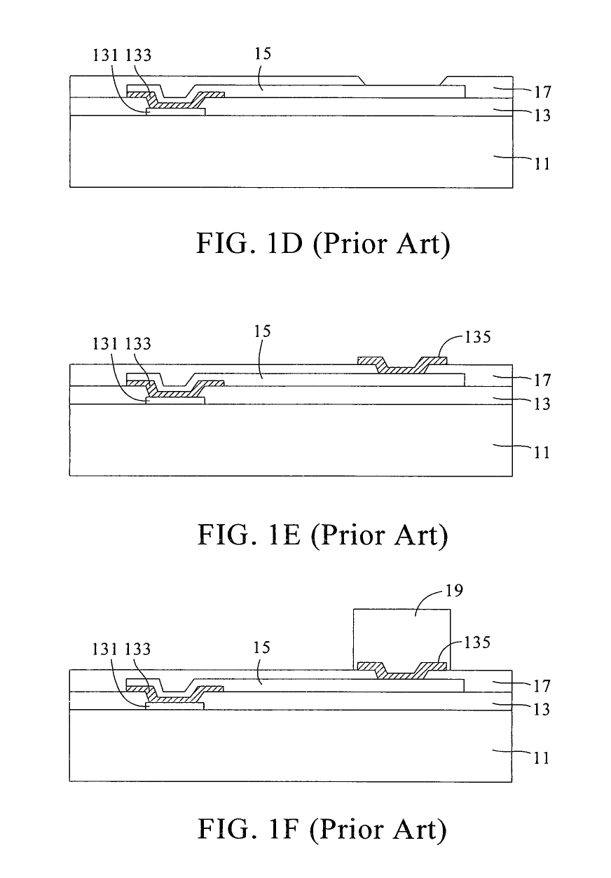

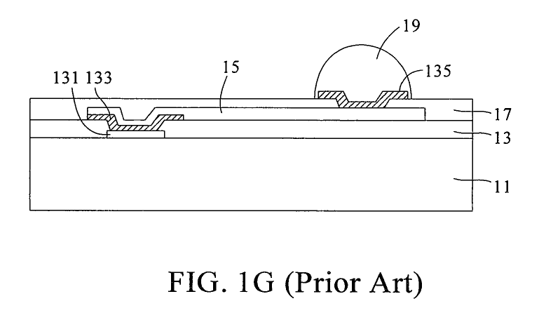

### DESCRIPTION OF THE PREFERRED EMBODIMENT

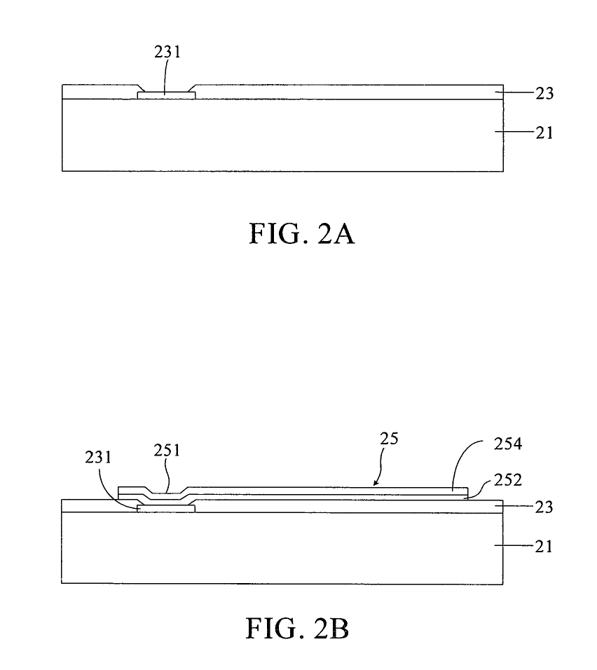

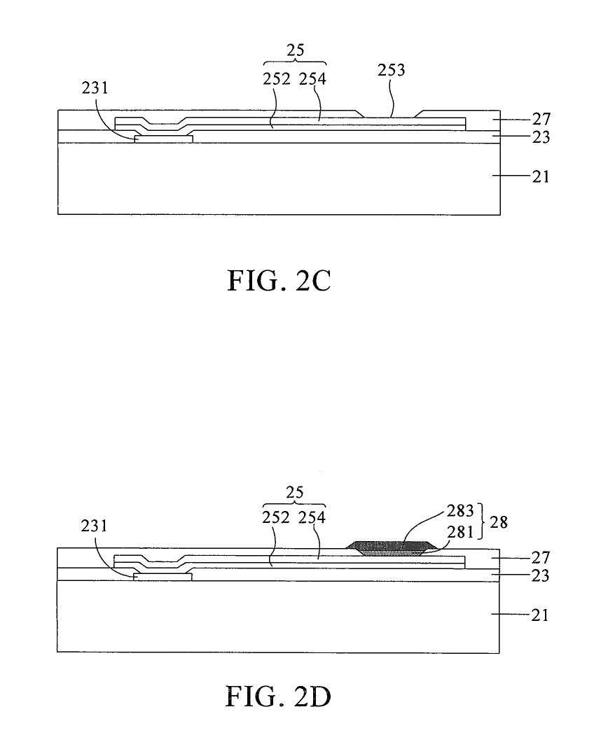

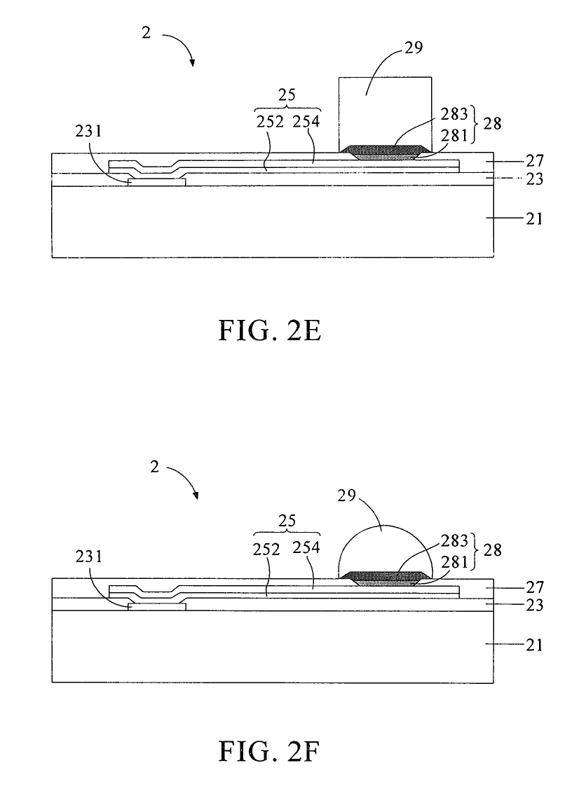

FIGS. 2E and 2F are schematic views of a conductive structure 2 for packaging a chip 21 according to this invention. The conductive structure 2 comprises a redistribution layer 25, a UBM 28 and a bump 29.

To explain the structure and the method of this invention more clearly, descriptions will be made with reference to the attached drawings according to the process sequence. In reference to FIG. 2A, the chip 21 comprises a first passivation layer 23 and a pad 231, in which the pad 231 is made of Al or Cu. More specifically, the first passivation layer 23 partially overlays the pad 231 and has the pad 231 partially exposed therethrough, so that the first passivation layer 23 and the pad 231 together define an active surface. The pad 231 is exposed on the active surface.

Next, as shown in FIG. 2B, a redistribution layer 25 is then formed on the active surface of the chip 21. More specifically, the redistribution layer 25 is formed on the first passivation layer 23 of the chip 21 and electrically connected to the pad 231 through a first conductive area 251 thereof. The redistribution layer 25 are formed as the following steps. Initially, a barrier layer 252 is sputtered to overlay the first passivation layer 23 and the pad 231. Next, a conductive layer 254 is sputtered on the barrier layer 252. Finally, the barrier layer 252 and the conductive layer 254 are patterned through a photolithographic process to form a conductive structure for electrical connection. The barrier layer 252 should be a Ti/W metal layer, while the conductive layer 254 is formed by sputtering Au, Al, or Cu. However, the materials of the layers are not merely limited thereto, and any conductive material may be used as the material of the conductive layer 254. Accordingly, a combination of materials of the barrier layer 252 and the conductive layer 254 may be selected depending on practical requirements. For example, TiW—Au, Ti—Cu, TiW—Cu, Ti—Al, Ti—NiV—Cu, Ti(W)—Ni or the like. Besides preventing the metal materials of the conductive layer 254 (e.g., Au) and the pad 231 (Al or Cu) from diffusing into each other, the barrier layer 252 may also enhance the adhesion between these materials.

Next, in reference to FIG. 2C, a second passivation layer 27 is formed to overlay the redistribution layer 25 and patterned through a photolithographic process to partially expose the second conductive area 253 of the redistribution layer 25.

Subsequently, as shown in FIG. 2D, a UBM 28 is formed on the second conductive area 253 to be electrically connected to the redistribution layer 25. This invention is unique in that the UBM 28 is an electroless plating layer. In other words, the patterning step of the photolithographic process in the prior art method is eliminated, and thus saving use of photomasks and the associated lithographic process. The UBM 28 should be formed by forming an Ni layer 281 and an Au layer 283 in sequence through the electroless plating process, in which the Ni layer 281 is formed directly on the second conductive area 253 and the Au layer 283 is subsequently formed on the Ni layer 281. It should be noted that the material of the UBM 28 is not merely limited to Ni/Au and other materials may also be used instead by those of ordinary skill in the art, so no limitation is made herein.

Finally, as shown in FIG. 2E, the bump 29 is formed on the UBM 28 to be electrically connected thereto. More specifically, the bump 29 is electrically connected to the Au layer 283 of the UBM 28. The bump 29 may be made of Sn or a terne metal, but it is not merely limited thereto. The bump 29 may be reflowed to form a ball bump, as shown in FIG. 2F.

In the manufacturing process and the structure thus formed of this invention, the UBM is formed through an electroless plating process. This, apart from advantageously providing the UBM with a uniform thickness, may further save the use of at least one photomask and the associated photolithographic process to simplify the manufacturing process, thus increasing the production output, reducing the cost and ensuring a higher yield.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A conductive structure of a chip, comprising:
a redistribution layer (RDL) formed on the chip, the redistribution layer having a first conductive area and a second conductive area, and electrically connecting to the chip through the first conductive area thereof;
an under bump metal (UBM) formed on the redistribution layer and electrically connecting to the redistribution layer through the second conductive area, wherein the UBM is an electroless plating layer; and
a bump formed on and electrically connecting to the UBM.

2. The conductive structure as claimed in claim 1, wherein the chip is defined with an active surface and at least includes a pad being exposed on the active surface, the redistribution layer being formed on the active surface and electrically connected to the pad at the first conductive area thereof.

3. The conductive structure as claimed in claim 2, wherein the electroless plating layer is made of Ni and Au.

4. The conductive structure as claimed in claim 3, wherein the chip further comprises a first passivation layer which partially exposes the pad and forms the active surface with the pad.

5. The conductive structure as claimed in claim 4, further comprising a second passivation layer overlaying the redistribution layer and partially exposing the second conductive area, wherein the electroless plating layer is electrically connected to the redistribution layer through the second conductive area thereof.

6. The conductive structure as claimed in claim 5, wherein the electroless plating layer comprises an Ni layer and an Au layer, in which the Ni layer is formed on the second conductive area and the Au layer is formed on the Ni layer to electrically connect to the bump.

7. The conductive structure as claimed in claim 6, wherein the redistribution layer is composed of a barrier layer and a conductive layer, in which the barrier layer overlays the first passivation layer and electrically connects to the pad and the conductive layer overlays the barrier layer.

8. The conductive structure as claimed in claim 7, wherein the barrier layer is a Ti/W metal layer.

9. The conductive structure as claimed in claim 7, wherein the conductive layer is made of one of Au, Cu, and Al.

10. The conductive structure as claimed in claim 2, wherein the pad is made of one of Al and Cu.

11. A method for manufacturing a conductive structure, comprising:
forming a redistribution layer on a chip, wherein the redistribution layer has a first conductive area to electrically connect to the chip therethrough;
forming an under bump metal (UBM) by an electroless plating process to electrically connect to the redistribution layer through a second conductive area thereof; and
forming a bump electrically connecting to the UBM.

12. The method as claimed in claim 11, wherein the step of forming a redistribution layer is forming the redistribution layer on a first passivation layer of the chip to electrically connect to a pad of the chip.

13. The method as claimed in claim 12, further comprising a step after the step of forming the redistribution layer:
partially exposing the redistribution layer at the second conductive area thereof.

14. The method as claimed in claim 13, wherein the step of partially exposing the redistribution layer comprises:
forming a second passivation layer overlaying the redistribution layer; and
patterning the second passivation layer to expose the second conductive area.

15. The method as claimed in claim 12, wherein the step of forming a redistribution layer comprises:
sputtering a barrier layer overlaying the first passivation layer and the pad;
sputtering a conductive layer on the barrier layer; and
patterning the barrier layer and the conductive layer.

16. The method as claimed in claim 15, wherein the step of sputtering a barrier layer is sputtering a Ti/W metal layer, and the step of sputtering a conductive layer is sputtering one of Au, Al, and Cu.

17. The method as claimed in claim 16, wherein the step of forming a bump is forming the bump to electrically connect to an Au layer of the UBM.

18. The method as claimed in claim 11, wherein the step of forming a bump further comprises reflowing the bump.

19. The method as claimed in claim 11, wherein the step of forming a UBM is forming an Ni layer and an Au layer, the Ni layer being formed at the second conductive area to electrically connect to the redistribution layer, and the Au layer being formed on the Ni layer.
